(19) United States
(12) Patent Application Publication
(10) Pub. No.: US 2022/0064780 A1
(43) Pub. Date: Mar. 3, 2022

(54) MASK ASSEMBLY

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventors: Qian XU, Beijing (CN); Jianpeng WU, Beijing (CN); Chang LUO, Beijing (CN); Fengli JI, Beijing (CN)

(21) Appl. No.: 17/416,905

(22) PCT Filed: Aug. 11, 2020
(86) PCT No.: PCT/CN2020/108324

§ 371 Date: Jun. 21, 2021

(30) Foreign Application Priority Data
Aug. 12, 2019 (CN) 201921302981.X

(51) Int. Cl. C23C 14/04; C23C 14/24

(52) U.S. Cl. CPC C23C 14/042; C23C 14/24

(57) ABSTRACT

A mask assembly includes a mesh mask, a frame connected to a periphery of the mesh mask, and at least one support bar. The at least one support bar and the frame support the mesh mask together. Each support bar has a first end fixed to one side portion of the frame and a second end fixed to another side portion of the frame.

### CROSS-REFERENCE TO RELATED APPLICATIONS

This application is a national phase entry under 35 USC 371 of International Patent Application No. PCT/CN2020/108324 filed on Aug. 11, 2020, which claims priority to Chinese Patent Application No. 201921302981.X, filed on Aug. 12, 2019, which are incorporated herein by reference in their entirety.

### TECHNICAL FIELD

The present disclosure relates to the field of semiconductor process, and more particularly, to a mask assembly. The mask assembly, for example, may be used for the manufacture of organic light-emitting diode (OLED) display devices.

### BACKGROUND

OLED display technology has become one of the mainstream development directions in the field of display technology due to that apparatuses using this technology have advantages of thin and light, wide viewing angle, high brightness, and colorful colors.

The mainstream manufacturing process of OLED devices is a process of evaporating a luminescent material using a metal mask assembly, and the metal mask assembly for evaporation is assembled by fixing a mesh mask to a metal frame through a process such as tensioning and welding. When the mesh mask is welded to the frame, in order to ensure that sagging amount of the mesh mask meets specification requirements, it is necessary to apply a certain amount of mesh tension to the mesh mask.

### SUMMARY

A mask assembly is provided. The mask assembly includes a mesh mask, a frame, and at least one support bar. The frame is connected to a periphery of the mesh mask. Each support bar has a first end fixed to one side portion of the frame and a second end fixed to another side portion of the frame. The support bar and the frame support the mesh mask together.

In some embodiments, the mesh mask includes: at least one first rib extending in a first direction, and at least one second rib extending in a second direction intersecting with the first direction. The at least one second rib and the at least one first rib intersect with each other. An orthographic projection of the support bar on a reference plane falls within an orthographic projection of a rib corresponding to the support bar on the reference plane, the rib is a first rib or a second rib, and the reference plane is a plane parallel to the mesh mask.

In some embodiments, the at least one support bar includes a first group of support bars extending in the first direction, and the first group of support bars includes one or more support bars.

In some embodiments, the at least one support bar includes a second group of support bars extending in the second direction, and the second group of support bars includes one or more support bars.

In some embodiments, an orthographic projection of an inner border of the frame on the reference plane is in a shape of a rectangle, and the rectangle has long sides and short sides. The at least one support bar includes a first group of support bars extending in a direction parallel to the short sides of the rectangle or a second group of support bars extending in a direction parallel to the long sides of the rectangle. The first group of support bars and the second group of support bars each include one or more support bars.

In some embodiments, the first group of support bars includes a plurality of support bars symmetrically distributed with respect to a symmetry axis of the long sides; or the second group of support bars includes a plurality of support bars symmetrically distributed with respect to a symmetry axis of the short sides.

In some embodiments, an orthographic projection of an inner border of the frame on the reference plane is in a shape of a rectangle, and the rectangle has long sides and short sides. The at least one support bar includes a first group of support bars extending in a direction parallel to the short sides of the rectangle and a second group of support bars extending in a direction parallel to the long sides of the rectangle. The first group of support bars and the second group of support bars each include one or more support bars.

In some embodiments, the first group of support bars includes a plurality of support bars symmetrically distributed with respect to a symmetry axis of the long sides; and the second group of support bars includes a plurality of support bars symmetrically distributed with respect to a symmetry axis of the short sides.

In some embodiments, the first direction is parallel to the short sides of the rectangle, and the second direction is not parallel to the long sides of the rectangle; or the first direction is not parallel to the short sides of the rectangle, and the second direction is parallel to the long sides of the rectangle; or the first direction is parallel to the short sides of the rectangle, and the second direction is parallel to the long sides of the rectangle.

In some embodiments, the frame has at least one first accommodating groove and at least one second accommodating groove. A first end of one or more support bars is provided in a first accommodating groove, and a second end of one or more support bars is provided in a second accommodating groove.

In some embodiments, a depth of each of the first accommodating groove and the second accommodating groove is greater than or equal to a thickness of the support bar in a direction perpendicular to the reference plane.

In some embodiments, an inner peripheral surface of the frame has at least one mask accommodating groove; and the mesh mask is fixed at the at least one mask accommodating groove.

In some embodiments, the mesh mask is fixed on a surface of the frame.

In some embodiments, the at least one mask accommodating groove includes one annular mask accommodating groove provided on the inner peripheral surface of the frame; or the at least one mask accommodating groove includes a plurality of mask accommodating grooves sequentially arranged on the inner peripheral surface of the frame.

In some embodiments, the first accommodating groove and the second accommodating groove are both located at a bottom of the at least one mask accommodating groove in a direction perpendicular to a reference plane, and the reference plane is a plane parallel to the mesh mask.

In some embodiments, the support bar contacts and supports the rib in the mesh mask corresponding to the support bar.

In some embodiments, a thickness of the support bar in a direction perpendicular to a plane where the mesh mask is located is from 50 micrometers to 100 micrometers.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings in the following description may be regarded as schematic diagrams, which are not limitations on an actual size of a product, an actual process of a method and an actual timing of signals involved in the embodiments of the present disclosure.

FIG. 1 is a bottom view of a mask assembly, in accordance with some embodiments of the present disclosure;

FIG. 2 is a bottom view of another mask assembly, in accordance with some embodiments of the present disclosure;

FIG. 3 is a bottom view of yet another mask assembly, in accordance with some embodiments of the present disclosure;

FIG. 4 is a sectional view of a mask assembly in FIG. 1 taken along the line A-A′;

FIG. 5 is a sectional view of an alternative structure to a structure as shown in FIG. 4;

FIG. 6 is a groove for accommodating a support bar in a frame, in accordance with some embodiments of the present disclosure; and

FIG. 7 is a groove for accommodating a support bar in another frame, in accordance with some embodiments of the present disclosure.

### DETAILED DESCRIPTION

The technical solutions in some embodiments of the present disclosure will be described clearly and completely with reference to the accompanying drawings. Obviously, the described embodiments are merely some but not all of embodiments of the present disclosure. All other embodiments made on the basis of the embodiments of the present disclosure by a person of ordinary skill in the art shall be included in the protection scope of the present disclosure.

Unless the context requires otherwise, the term “comprise” and other forms thereof such as the third-person singular form “comprises” and the present participle form “comprising” throughout the description and the claims are construed as an open and inclusive meaning, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or examples(s). In addition, the specific features, structures, materials, or characteristics described herein may be included in any one or more embodiments or examples in any suitable manner.

It can be understood that the description of some embodiments herein is only for illustration and explanation of an overall concept of the present disclosure, but not for limitation to the present disclosure. In the specification and drawings, the same or similar reference sign(s) refer to the same or similar part(s) or component(s). For clarity, the drawings are not necessarily drawn to scale, and some well-known components and structures may be omitted from the drawings.

Unless otherwise defined, technical terms or scientific terms used in the present disclosure should have common meanings understood by a person of ordinary skill in the art to which the present disclosure belongs. The words “first”, “second” and the like used in the present disclosure are not intended to mean any order, quantity or importance, but are merely used to distinguish different components. The wording “a” or “an” does not exclude a plurality. The word “include”, “contain” or the like means that an element or object appearing before the word has element(s) or object(s) and the equivalent thereof listed after the word, without excluding other element(s) or object(s). The phrase “connected to”, “connected with” or the like is not limited to a physical or mechanical connection, but may include an electrical connection, whether direct or indirect. “On”, “under”, “left”, “right”, “top”, “bottom” or the like is only used to indicate a relative positional relationship, and when the absolute position of a described object is changed, the relative positional relationship may also be changed accordingly. When an element such as a layer, film, region, or substrate is referred to as being “on” or “under” another element, the element may be “directly” “on” or “under” the another element, or there may be intermediate element(s).

In addition, the use of the phrase “based on” means openness and inclusiveness, because processes, steps, calculations or other actions “based on” one or more of the stated conditions or values may be based on additional conditions or values exceeding those stated in practice.

In the semiconductor processing technology, an evaporation process is an important process. For example, in the processing technology for manufacturing organic light-emitting diode (OLED) devices, a luminescent material layer may be deposited using the evaporation process. In the evaporation process, a mesh mask is required to realize a patterning of a structural layer (e.g., the luminescent material layer). Therefore, the accuracy of the mesh mask is crucial to the accuracy of a processed product. As mentioned above, the metal mask assembly for evaporation may be assembled by tensioning and fixing the mesh mask to the frame through the process such as tensioning and welding. It is necessary to apply tension to the mesh mask in order to maintain a good flatness thereof.

The inventors of the present disclosure have discovered through research that tension received by the mesh mask will reversely act on the frame, resulting in deformation of the frame, and this deformation will affect the tensioning and evaporation accuracy of the mesh mask. The deformation of the frame is closely related to mesh tension of the mesh mask. If the deformation of the frame is needed to be reduced, it is inevitable to reduce the mesh tension of the mesh mask. However, the reduction of the mesh tension will increase the sagging amount of the mesh mask, resulting in poorer tensioning and evaporation quality. Therefore, it is necessary to find a mask assembly structure that may simultaneously ameliorate the sagging amount of the mesh mask and the deformation of the frame.

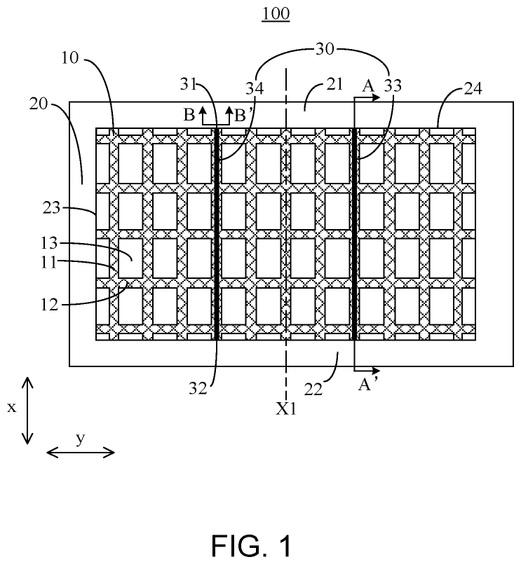

In order to alleviate the above problems, some embodiments of the present disclosure provide a mask assembly 100. As shown in FIG. 1, the mask assembly 100 includes a mesh mask 10, a frame 20 and at least one support bar 30.

The mesh mask 10 is one of the main parts of the mask assembly 100. In the evaporation process, a pattern in a structure layer is formed based on a shape of the mesh mask 10. The specific shape of the mesh mask 10 may be determined according to the desired pattern formed by the mask assembly 100. For simplicity, only a simple structure of rectangular grid is shown in FIG. 1, but some other embodiments of the present disclosure are not limited thereto.

The frame 20 is connected to a periphery of the mesh mask 10 to support the mesh mask 10. The specific connection manner of the frame 20 and the mesh mask 10 may include a fixed installation manner such as welding. In some embodiments, the mesh mask 10 may be fixed on the frame 20 after being tensioned, and the frame 20 may support the mesh mask 10 and maintain a tension state of the mesh mask 10.

At least one support bar 30 may have a first end 31 and a second end 32. The first end 31 is fixed to one side portion 21 of the frame 20, and the second end 32 is fixed to another side portion of the frame 20. Therefore, the support bar 30 and the frame 20 support the mesh mask 10 together.

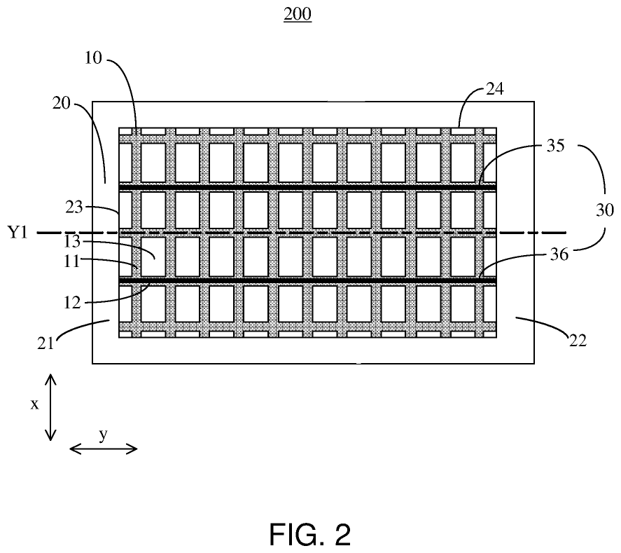

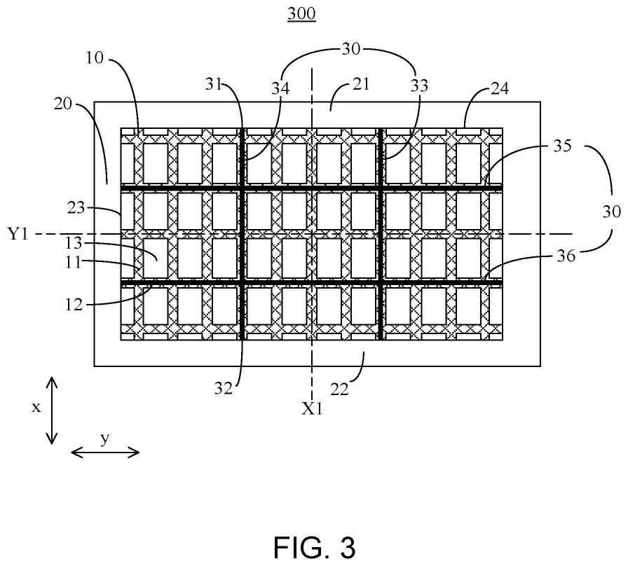

It will be noted that in each embodiment of the present disclosure, the “one side portion” and the “another side portion” of the frame 20 for fixing the first end 31 and the second end 32 of the support bar 30 respectively do not specifically refer to some side portions of the frame 20, but may be any side portions of the frame 20. For example, in embodiments of FIGS. 1 and 3, the two ends of the support bar 30 may be fixed to an upper side portion and a lower side portion of the frame 20, respectively, or in embodiments of FIG. 2, the two ends of the support bar 30 may be fixed to a left side portion and a right side portion of the frame 20, respectively. In a case where the mask assembly includes a plurality of support bars 30, ends of different support bars 30 may be fixed to a same side portion of the frame 20, or may be fixed to different side portions of the frame 20. In other words, extension directions of different support bars 30 may be the same or different. In some embodiments, the side portions of the frame 20 may be straight or curved.

In some of the above embodiments, not only the frame 20 is used to support the mesh mask 10, but the support bars 30 may also play an auxiliary supporting role for the mesh mask 10. For example, the mesh tension required by the mesh mask 10 may be reduced, thereby reducing the deformation of the frame 20 to improve the accuracy of patterning (e.g., during the evaporation process) using the mask assembly 100, and avoiding affecting product yield due to defects such as color mixing.

In some embodiments, the mesh mask 10 may include: at least one first rib 11 extending in the first direction (as shown in the x direction in FIG. 1) and at least one second rib 12 extending in the second direction (as shown in they direction in FIG. 1). In the example shown in FIG. 1, the x direction and the y direction are perpendicular to each other, but embodiments of the present disclosure are not limited to thereto, as long as the second direction and the first direction intersect with each other. In this way, the at least one second rib 12 and the at least one first rib 11 can intersect with each other to form a mesh structure of the mesh mask 10. During the evaporation process, the evaporated material may be blocked by the first rib(s) 11 and the second rib(s) 12 but may pass through the mesh hole 13 between the first rib(s) 11 and the second rib(s) 12 to realize the patterning of the evaporated material layer. It will be understood that there may be one or more first ribs 11 in each embodiment of the present disclosure; similarly, there may be one or more second ribs 12 in each embodiment of the present disclosure.

In some embodiments, referring to FIG. 1, the mask assembly 100 may include support bars 30. At least one support bar 30 may be provided corresponding to a rib of the above first rib(s) 11 and second rib(s) 12. An orthographic projection of the support bar 30 on a reference plane falls within an orthographic projection of the rib corresponding to the support bar 30 on the reference plane. The rib corresponding to the support bar 30 may be a first rib 11 or a second rib 12. The reference plane is a plane parallel to the mesh mask 10 (e.g., plane defined by the x direction and they direction in FIG. 1).

This arrangement may ensure that during the patterning process using the mask assembly 100, the support bar 30 will not block the mesh hole 13 between the first rib(s) 11 and the second rib(s) 12, thereby preventing the support bar 30 from affecting the patterning accuracy of the mask assembly 100.

In this case, a width of each support bar 30 is less than or equal to a width of a rib of the mesh mask 10 corresponding to the support bar 30. This may prevent the support bar 30 from exceeding a range of the corresponding rib of the mesh mask 10 in width, so that the support bar 30 may play a supporting role without hindering the normal operation of the mask assembly 100. As an example, the width of the support bar 30 may be on the order of millimeters, for example, in a range of 5 millimeters to 10 millimeters.

In some embodiments of the present disclosure, the support bar 30 contacts and supports the rib in the mesh mask 10 corresponding to the support bar 30. This may make the support bar 30 actually play a supporting role.

In some embodiments, the support bar 30 may be in a substantially cuboid shape, and the orthographic projection of the support bar 30 on the reference plane has a uniform width, but the embodiments of the present disclosure are not limited to thereto. For example, in some other embodiments, the width of the orthographic projection of the support bar 30 on the reference plane may also be changed to a certain extent.

In some embodiments, the mask assembly may include one or more support bars only extending in the same direction. For example, in the mask assembly 100 as shown in FIG. 1, two support bars 33, 34 are shown, and the two support bars (33, 34) both extend in the first direction (x). In the mask assembly 200 as shown in FIG. 2, two support bars (35, 36) as shown both extend in the second direction (y). In some other embodiments, the mask assembly may include a first group of support bars extending in a first direction and a second group of support bars extending in a second direction. For example, in the mask assembly 300 as shown in FIG. 3, two support bars (33, 34) extending in a first direction (x) and two support bars (35, 36) extending in a second direction (y) are provided. The support bars (33, 34) extending in the first direction (x) may be regarded as the first group of support bars, and the support bars (35, 36) extending in the second direction (y) may be regarded as the second group of support bars mentioned above.

It will be noted that the type of support bar may be selected according to factors such as the specific shape of the mesh mask 10, the magnitude of the mesh tension, and the material of the frame 20 in practice. Generally speaking, two groups of support bars (such as the first group of support bars and the second group of support bars mentioned above) intersecting with each other may further increase the design flexibility of the frame 20 to obtain good results.

In some embodiments of the present disclosure, the first group of support bars may include one or more support bars, the second group of support bars may include one or more support bars. In each embodiment of the present disclosure, the number of support bars is not limited, and the specific number of each group of support bars may be selected according to actual needs.

In some embodiments, the orthographic projection of an inner border of the frame 20 on the reference plane is in a rectangle shape, and the rectangle has long sides 24 and short sides 23. As shown in FIG. 1, the mask assembly 100 may include a first group of support bars (33, 34) extending in a direction parallel to the short sides 23 of the frame 20; or as shown in FIG. 2, the mask assembly 200 may include a second group of support bars (35, 36) extending in a direction of the long sides 24 of the frame.

In some other embodiments, as shown in FIG. 3, the orthographic projection of the inner border of the frame 20 on the reference plane is also a rectangular shape. The rectangle has a long side 24 and a short side 23. The mask assembly includes a first group of support bars (33, 34) extending in a direction parallel to the short side 23 of the frame 20 and a second group of support bars (35, 36) extending in a direction parallel to the long side 24 of the frame.

In the above embodiments, the orthographic projection of the inner border of the frame 20 on the reference plane is of a rectangular structure, and the two ends of the support bar 30 are respectively fixed to two side portions of the frame 20 opposite to each other (e.g., upper and lower side portions, or left and right side portions). This structure has good stability, and the effect of supporting of support bars and compensating for frame deformation is also good. In some embodiments, in a case where there are a plurality of support bars extending in the direction parallel to the short sides 23 of the frame 20, these support bars may be symmetrically distributed in the symmetry axis X1 of the long sides 24; similarly, in a case where there are a plurality of support bars extending in the direction parallel to the long sides 24 of the frame 20, these support bars may be symmetrically distributed in the symmetry axis Y1 of the short sides 23.

In some examples, referring to FIG. 1, the above first direction x is parallel to the short sides 23 of the rectangle. This arrangement enables the support bar(s) 30 parallel to the short sides 23 of the rectangle may be parallel to the ribs extending in the first direction x in the mesh mask 10, thereby achieving a stable support effect and improving the patterning accuracy of the mask assembly.

In some other examples, referring to FIG. 2, the above second direction y is parallel to the long sides 24 of the rectangle. This arrangement enables the support bar 30 parallel to the long sides 24 of the rectangle may be parallel to the ribs extending in the second direction y in the mesh mask 10, thereby achieving a stable support effect and improving the patterning accuracy of the mask assembly.

In yet some other examples, referring to FIG. 3, the first direction x is parallel to the short sides 23 of the rectangle, and the second direction y is parallel to the long sides 24 of the rectangle. This arrangement enables the support bar 30 parallel to the long sides 24 of the rectangle may be parallel to the ribs extending in the second direction y in the mesh mask 10, and enables the support bar 30 parallel to the long sides 24 of the rectangle may be parallel to the ribs extending in the second direction y in the mesh mask 10, thereby achieving a stable support effect and improving the patterning accuracy of the mask assembly.

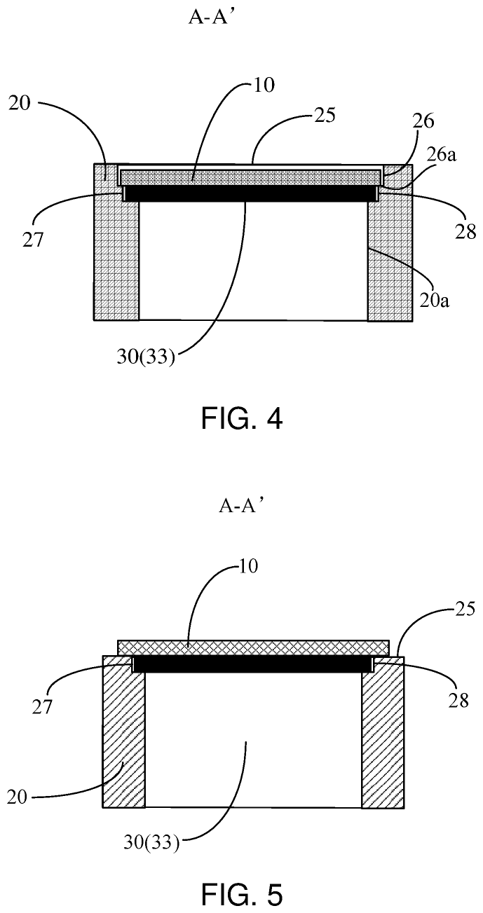

FIG. 4 is a sectional view of the mask assembly 100 in FIG. 1 taken along the line A-A′, and FIG. 5 is a sectional view of an alternative structure to a structure as shown in FIG. 4.

In some embodiments, referring to FIGS. 4 and 5, the frame has at least one first accommodating groove 27 and at least one second accommodating groove 28. a first end 31 of one or more support bars 30 may be provided in a first accommodating groove 27 on the frame 20, and a second end 32 of one or more support bars 30 may be provided in a second accommodating groove 28 on the frame 20.

In some embodiments, referring to FIG. 4, an inner peripheral surface 20a of the frame 20 has a mask accommodating groove 26, and the mesh mask 10 is fixed at the mask accommodating groove 26.

FIGS. 4 and 5 show two examples of the mutual positional relationship of the support bar 30, the mesh mask 10, and the frame 20 in a direction (e.g., vertical direction) perpendicular to the reference plane, respectively. In the example of FIG. 4, the mesh mask 10 is embedded in the mask accommodating groove 26 on the inner peripheral surface of the frame 20. Referring to FIG. 4, there may be one mask accommodating groove 26, for example, the mask accommodating groove 26 may be an annular groove on the inner peripheral surface of the frame 20, and the groove may be open at a side facing towards an upper surface 25 of the frame 20 (or it is said that a side of the mask accommodating groove 26 away from the support bar 30 is open). In addition, there may be a plurality of mask accommodating grooves 26. In this case, the plurality of mask accommodating grooves 26 may be arranged to be sequentially arranged on the inner peripheral surface of the frame. Correspondingly, ends of one or more ribs in the mesh mask 10 may be provided in a corresponding mask accommodating groove 26. Such a design is beneficial to improve the overall structural strength of the frame 20, so that the frame 20 is not prone to deformation. Therefore, when the mask assembly is formed, it is beneficial to improve the mesh tension and evaporation precision of the mesh mask.

In order to play a supporting role, the support bar 30 may be located below the mesh mask 10. For example, the first end 31 of the support bar 30 may be provided in the first accommodating groove 27 that is on the frame 20 and located below the mask accommodating groove 26. The second end 32 of the support bar 30 may be provided in the second accommodating groove 28 that is on the frame 20 and located below the mask accommodating groove 26. In other words, the first accommodating groove 27 and the second accommodating groove 28 are located on the same side of the mask accommodating groove 26 in a direction perpendicular to a plane where the mesh mask 10 is located, for example, the first accommodating groove 27 and the second accommodating groove 28 are both located on a bottom 26a of the mask accommodating groove 26.

In the example of FIG. 5, the mesh mask 10 is fixed on the upper surface 25 of the frame 20 (the surface of the frame 20 facing upward when the mask assembly is working). In this case, the support bar 30 may also be located below the mesh mask 10. For example, the first end 31 of the support bar 30 may be accommodated in the first accommodating groove 27 on the frame 20, and the second end 32 of the support bar 30 may be accommodated in the second accommodating groove 28 on the frame 20. In this example, since the mesh mask 10 is fixed to the upper surface 25 of the frame 20, the position of the support bar 30 may be closer to the upper surface 25 of the frame 20 compared to the example shown in FIG. 4.

It will be noted that, FIGS. 1 to 3 all adopt a bottom view in order to better show the support bar 30. Due to the shielding relationship, whether the mesh mask 10 is fixed to the mask accommodating groove 26 on the inner peripheral surface of the frame 20 or to the upper surface 25 of the frame 20, the bottom view is the same as shown in FIG. 1. Therefore, bottom views corresponding to the sectional views of FIGS. 4 and 5 both may be regarded as FIG. 1.

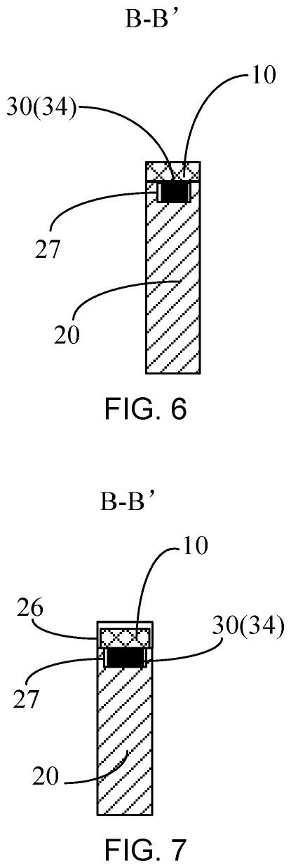

In some embodiments of the present disclosure, a depth of each of the first accommodating groove 27 and the second accommodating groove 28 may be greater than or equal to a thickness of the support bar 30 in a direction perpendicular to the reference plane. FIGS. 6 and 7 schematically show two different examples of sectional views taken along the line B-B′ in FIG. 1 in order to show the first accommodating groove 27 and the second accommodating groove 28 more clearly. FIG. 6 corresponds to FIG. 5, and FIG. 7 corresponds to FIG. 4. In FIG. 6, it may be seen that the first accommodating groove 27 (or the second accommodating groove 28) is located below the mask accommodating groove 26. In FIG. 7, it may be seen that the first accommodating groove 27 (or the second accommodating groove 28) is located proximate to the upper surface 25 of the frame 20.

In some embodiments, the depth of each of the first accommodating groove 27 and the second accommodating groove 28 in the direction perpendicular to the reference plane is desired to be consistent with the thickness of the support bar 30 in the direction perpendicular to the reference plane. It allows the support bar 30 to support the mesh mask 10 better. In addition, the above depth of each of the first accommodating groove 27 and the second accommodating groove 28 may be slightly larger than the above thickness of the support bar 30 considering that the mesh mask 10 may have certain sagging amount. For example, the above depth of each of the first accommodating groove 27 and the second accommodating groove 28 may be greater than the aforementioned thickness of the support bar 30 within 10 micrometers.

In some embodiments of the present disclosure, the thickness of the support bars in a direction perpendicular to the plane where the mesh mask is located is of 50 micrometers to 100 micrometers. Through this design, not only may the support bar 30 support the mesh mask 10 good, but may also avoid a situation where the evaporation material is blocked by the support bar because the thickness of the support bar 30 is too large, and thus cannot form the structure layer effectively. Here, it will be noted that the thickness of the support bar in each embodiment of the present disclosure is not limited thereto. That is, the support bar 30 may also have other thickness according to different evaporation requirements.

In some embodiments of the present disclosure, the mesh mask 10, the frame 20, and the support bar 30 may be made of metal material(s) (for example, the mesh mask 10 and the support bar 30 may be made of silver, aluminum, etc.), or made of any other material that can withstand the mesh tension.

The mask assembly 100, 200, or 300 according to some embodiments of the present disclosure, may be used for patterning in an evaporation process, but the embodiments of the present disclosure are not limited thereto, and the mask assembly may also be used for other purposes.

Although the present disclosure has been described with reference to the accompanying drawings, the embodiments disclosed in the accompanying drawings are intended to exemplify the embodiments of the present disclosure, and should not be understood as a limitation of the present disclosure. The dimension scales in the drawings are only schematic and should not be construed as limiting the present disclosure.

The foregoing descriptions are merely specific implementations of the present disclosure, but the protection scope of the present disclosure is not limited thereto, and changes or replacements that any person skilled in the art could conceive of within the technical scope of the present disclosure shall be included in the protection scope of the present disclosure. Therefore, the protection scope of the present disclosure shall be subject to the protection scope of the claims.

1. A mask assembly comprising:
a mesh mask;
a frame connected to a periphery of the mesh mask; and
at least one support bar, the at least one support bar and the frame supporting the mesh mask together, each support bar having:
a first end fixed to one side portion of the frame, and
a second end fixed to another side portion of the frame.

2. The mask assembly according to claim 1, wherein the mesh mask includes:
at least one first rib extending in a first direction; and
at least one second rib extending in a second direction intersecting with the first direction; wherein
the at least one second rib and the at least one first rib intersect with each other; and
an orthographic projection of the support bar on a reference plane falls within an orthographic projection of a rib corresponding to the support bar on the reference plane, the rib is a first rib or a second rib, and the reference plane is a plane parallel to the mesh mask.

3. The mask assembly according to claim 2, wherein the at least one support bar includes a first group of support bars extending in the first direction, and the first group of support bars includes one or more support bars.

4. The mask assembly according to claim 2, wherein an orthographic projection of an inner border of the frame on the reference plane is in a shape of a rectangle, and the rectangle has long sides and short sides; and
the at least one support bar includes a first group of support bars extending in a direction parallel to the short sides of the rectangle or a second group of support bars extending in a direction parallel to the long sides of the rectangle, and the first group of support bars and the second group of support bars each include one or more support bars.

5. The mask assembly according to claim 4, wherein the first group of support bars includes a plurality of support bars symmetrically distributed with respect to a symmetry axis of the long sides; or
the second group of support bars includes a plurality of support bars symmetrically distributed with respect to a symmetry axis of the short sides.

6. The mask assembly according to claim 2, wherein an orthographic projection of an inner border of the frame on the reference plane is in a shape of a rectangle, and the rectangle has long sides and short sides; and
the at least one support bar includes a first group of support bars extending in a direction parallel to the short sides of the rectangle and a second group of support bars extending in a direction parallel to the long sides of the rectangle, and the first group of support bars and the second group of support bars each include one or more support bars.

7. The mask assembly according to claim 6, wherein the first group of support bars includes a plurality of support bars symmetrically distributed with respect to a symmetry axis of the long sides; and
the second group of support bars includes a plurality of support bars symmetrically distributed with respect to a symmetry axis of the short sides.

8. The mask assembly according to claim 4, wherein
the first direction is parallel to the short sides of the rectangle, and the second direction is not parallel to the long sides of the rectangle; or
the first direction is not parallel to the short sides of the rectangle, and the second direction is parallel to the long sides of the rectangle; or
the first direction is parallel to the short sides of the rectangle, and the second direction is parallel to the long sides of the rectangle.

9. The mask assembly according to claim 1, wherein the frame has at least one first accommodating groove and at least one second accommodating groove; and
a first end of one or more support bars is provided in a first accommodating groove, and a second end of one or more support bars is provided in a second accommodating groove.

10. The mask assembly according to claim 9, wherein a depth of each of the first accommodating groove and the second accommodating groove is greater than or equal to a thickness of the support bar in a direction perpendicular to the reference plane.

11. The mask assembly according to claim 9, wherein an inner peripheral surface of the frame has at least one mask accommodating groove; and
the mesh mask is fixed at the at least one mask accommodating groove.

12. The mask assembly according to claim 11, wherein the at least one mask accommodating groove includes one annular mask accommodating groove provided on the inner peripheral surface of the frame; or
the at least one mask accommodating groove includes a plurality of mask accommodating grooves sequentially arranged on the inner peripheral surface of the frame.

13. The mask assembly according to claim 11, wherein the first accommodating groove and the second accommodating groove are both located at a bottom of the at least one mask accommodating groove in a direction perpendicular to a reference plane, and the reference plane is a plane parallel to the mesh mask.

14. The mask assembly according to claim 2, wherein the support bar contacts and supports the rib in the mesh mask corresponding to the support bar.

15. The mask assembly according to claim 1, wherein a thickness of the support bar in a direction perpendicular to a plane where the mesh mask is located is from 50 micrometers to 100 micrometers.

16. The mask assembly according claim 1, wherein the at least one support bar includes a second group of support bars extending in the second direction, and the second group of support bars includes one or more support bars.

17. The mask assembly according claim 6, wherein
the first direction is parallel to the short sides of the rectangle, and the second direction is not parallel to the long sides of the rectangle; or
the first direction is not parallel to the short sides of the rectangle, and the second direction is parallel to the long sides of the rectangle; or
the first direction is parallel to the short sides of the rectangle, and the second direction is parallel to the long sides of the rectangle.

18. The mask assembly according claim 9, wherein the mesh mask is fixed on a surface of the frame.
